(19) United States
(12) Patent Application Publication
(10) Pub. No.: US 2014/0326399 A1
(43) Pub. Date: Nov. 6, 2014

(54) LASER INDUCED THERMAL IMAGING APPARATUS AND LASER INDUCED THERMAL IMAGING METHOD USING THE SAME

(71) Applicant: Samsung Display Co., Ltd., Yongin-City (KR)

(72) Inventor: Tae Min KANG, Suwon-si (KR)

(73) Assignee: Samsung Display Co., Ltd., Yongin-City (KR)

(21) Appl. No.: 13/963,977

(22) Filed: Aug. 9, 2013

(30) Foreign Application Priority Data
May 2, 2013 (KR) 10-2013-0049522

(51) Int. Cl. H01L 51/00; H01L 51/50

(52) U.S. Cl. CPC H01L 51/0013; H01L 51/5012
USPC 156/237; 156/556; 156/540; 156/379.8; 156/60; 156/230

(57) ABSTRACT

A laser induced thermal imaging apparatus comprises a substrate support configured to support a substrate, a donor film holder configured to hold a donor film at a position over the substrate support, and a press unit comprising a first elastic member and a second elastic member disposed over the substrate support. The press unit is configured to move the first and second elastic members in a pressing direction toward the substrate support for pressing the donor film to the substrate to laminate the donor film onto the substrate. The second elastic member surrounds the first elastic member when viewed in the pressing direction and is more rigid than the first elastic member.

### CROSS-REFERENCE TO RELATED APPLICATION

This U.S. non-provisional patent application claims priority under 35 U.S.C. §119 of Korean Patent Application No. 10-2013-0049522, filed on May 2, 2013, the contents of which are hereby incorporated by reference in its entirety.

### BACKGROUND

1. Field of Disclosure

The present disclosure relates to a laser induced thermal imaging apparatus and a laser induced thermal image method using the same.

2. Discussion of the Related Technology

In recent years, organic light emitting displays have been spotlighted as a next generation display device since they have superior brightness and viewing angle and do not need to include a separate light source when compared to a liquid crystal display. Accordingly, the organic light emitting displays have advantages of slimness and lightweight. In addition, the organic light emitting displays have advantageous properties, e.g., fast response speed, low power consumption, high brightness, etc.

In general, the organic light emitting displays include an organic light emitting diode including an anode electrode, an organic light emitting layer, and a cathode electrode. Holes and electrons are injected into the organic emitting layer through the anode electrode and the cathode electrode, and are recombined in the organic light emitting layer to generate excitons (electron-hole pairs). The excitons emit energy, which is discharged when an excited state returns to a ground state, as light.

### SUMMARY

The present disclosure provides a laser induced thermal imaging apparatus capable of sequentially pressing a donor film over a substrate to be fixed to the substrate.

The present disclosure provides a laser induced thermal imaging apparatus using the laser induced thermal imaging apparatus.

Embodiments of the inventive concept provide a laser induced thermal imaging apparatus including a substrate support configured to support a substrate; a donor film holder configured to hold a donor film at a position over the substrate support; and a press unit comprising a first elastic member and a second elastic member disposed over the substrate support, and configured to move the first and second elastic members in a pressing direction toward the substrate support for pressing the donor film to the substrate to laminate the donor film onto the substrate, wherein the second elastic member surrounds the first elastic member when viewed in the pressing direction and is more rigid than the first elastic member.

The first elastic member has a thickness at a boundary thereof, which is greater than a thickness of the second elastic member, and the first elastic member has a first thickness at a first position and a second thickness at a second position which is closer to the boundary than the first position when viewed in the pressing direction, wherein the first thickness is greater than the second thickness.

The press unit further includes a press plate comprising a surface facing the substrate support, and the first and second elastic members are disposed over the surface of the press plate to face the substrate support.

The first and second elastic members are configured to move in the pressing direction to press the donor film to the substrate, and the donor film and the substrate are attached to each other in a non-deposition area of the substrate by an adhesive material.

The donor film holder comprise includes first and second film supporters placed at both side portions of the donor film to support the donor film.

The donor film includes a transfer layer that comprises the deposition material comprising an organic light emissive material for forming an organic light emitting layer over the substrate, a plurality of first holes formed through a first side portion of the donor film, and a plurality of second holes formed through a second side portion of the donor film.

The first film supporter includes a plurality of first protrusions configured to engage with the first holes, and the second film supporter includes a plurality of second protrusions configured to engage with the second holes to support the donor film at the first and second side portions.

The laser induced thermal imaging apparatus further includes a first chamber that accommodates the substrate support, the donor film holder, and the press unit so as to laminate the donor film over the substrate therein, and a second chamber configured to receive the substrate, on which the donor film is laminated, from the first chamber, a mask disposed in the second chamber and including a plurality of openings, and a laser beam irradiation unit disposed over the mask in the second chamber, and configured to irradiate a laser beam onto the donor film received in the second chamber through the openings such that the deposition material is transferred onto the substrate.

The laser induced thermal imaging apparatus further includes a third chamber configured to receive the substrate on which the deposition material is transferred, and a delamination roller disposed in the third chamber, including a plurality of third protrusions configured to engage with the first holes, and configured to roll to delaminate the donor film from the substrate.

Embodiments of the inventive concept provide a laser induced thermal imaging method of making a light emitting device comprising an organic light emissive layer including providing a substrate comprising a deposition surface that includes a deposition area and a non-deposition area surrounding the deposition area; providing a donor film comprising an adhesive material and a deposition material on a transfer surface thereof such that the transfer surface faces the substrate; providing a press unit movable along a pressing direction and comprising a first elastic member and a second elastic member surrounding the first elastic member when viewed in the pressing direction, wherein the second elastic member is more rigid than the first elastic member; arranging the press unit, the donor film and the substrate such that the donor film is located between the press unit and the substrate; and moving the first and second elastic members of the press unit toward the donor film to press the donor film onto the substrate and to laminate the donor film on the substrate, thereby laminating the donor film on the substrate, wherein the second elastic member presses the donor film such that the adhesive material is attached to the non-deposition area.

Embodiments of the inventive concept provide a method of making a light emitting device comprising an organic light emissive layer, the method comprising: providing a substrate support and a press unit configured to move along a pressing direction toward the substrate support, the press unit comprising: a first press member comprising a first press surface, and a second press member comprising a second press surface and surrounding the first press member when viewed in the pressing direction, wherein the first press surface is closer to the support than the second press surface; providing a substrate comprising a plurality of layers and a deposition surface; providing a donor film comprising a transfer surface and an organic light emissive material and an adhesive material which are provided on the transfer surface such that the adhesive material surrounds the adhesive material when viewed in the pressing direction; arranging the substrate and the donor film between the substrate support and the press unit such that the donor film is located between the substrate and the press unit and further such that the second press member overlaps the adhesive material when viewed in the pressing direction; and moving the first and second press members along the pressing direction toward the stage to press the donor film to the substrate, thereby attaching the donor film to the substrate using the adhesive material, wherein, while pressing, the organic light emissive material first contacts the substrate, and subsequently the adhesive material contacts and is attached to the substrate. In the foregoing method, when pressing, the first and second press members may move together, and the second press member has is more rigid than the first press member.

According to the above, the donor film may be sequentially pressed to and fixed to the substrate.

### BRIEF DESCRIPTION OF THE DRAWINGS

The above and other advantages of the present disclosure will become readily apparent by reference to the following detailed description when considered in conjunction with the accompanying drawings wherein:

FIG. 1 is a view showing a laser induced thermal imaging apparatus according to an exemplary embodiment of the present disclosure;

FIG. 2 is a view showing an inner configuration of a first chamber shown in FIG. 1;

FIG. 3 is a plan view showing an arrangement of a donor film and a substrate shown in FIG. 1;

FIG. 4 is a perspective view showing a first film supporter shown in FIG. 2;

FIG. 5 is a perspective view showing a press unit shown in FIG. 2;

FIG. 6 is a cross-sectional view showing a substrate shown in FIG. 2;

FIG. 7 is a cross-sectional view showing a structure of the donor film shown in FIG. 2;

FIGS. 8 to 10 are views showing a lamination process performed in the first chamber shown in FIG. 1;

FIG. 11 is a cross-sectional view showing the donor film pressed onto the substrate;

FIG. 12 is a view showing an inner configuration of a second chamber shown in FIG. 1;

FIG. 13 is a view showing a transfer process performed in the second chamber shown in FIG. 12;

FIG. 14 is a view showing an inner configuration of a third chamber shown in FIG. 1;

FIG. 15 is a view showing a delamination process performed in the third chamber shown in FIG. 14; and

FIG. 16 is a cross-sectional view showing an organic light emitting device manufactured after a laser induced thermal imaging process is performed.

### DETAILED DESCRIPTION

Hereinafter, embodiments of the present invention will be explained in detail with reference to the accompanying drawings.

Generally, organic light emitting layers of organic light emitting devices are formed by a printing method, e.g., an inkjet printing method, a nozzle printing method, etc., or a laser induced thermal imaging method. Among them, the laser induced thermal imaging method is performed by arranging a donor film including an organic material layer to face a substrate and irradiating a laser beam onto the donor film. Due to heat by the laser beam, the organic layer is transferred onto the substrate.

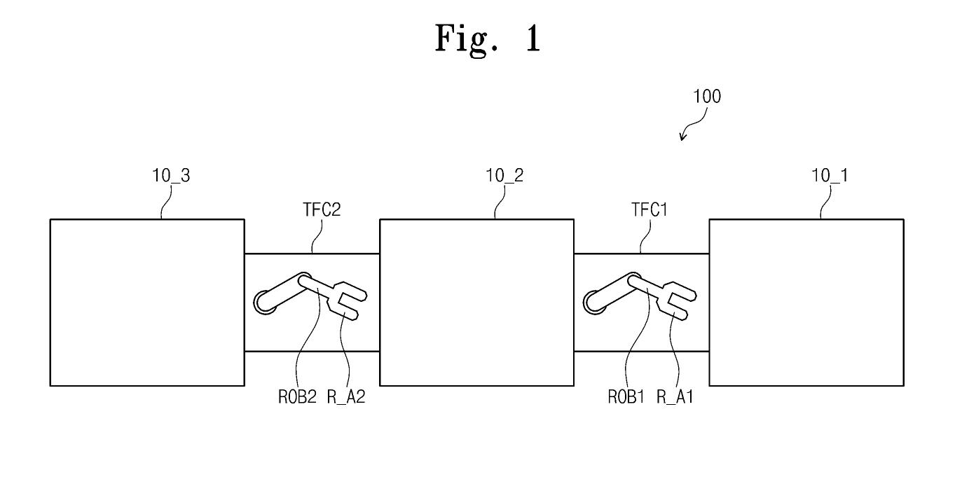

FIG. 1 is a view showing a laser induced thermal imaging apparatus 100 according to an exemplary embodiment of the present disclosure.

Referring to FIG. 1, in embodiments, the laser induced thermal imaging apparatus 100 includes a first chamber 10_1, a second chamber 10_2, a third chamber 10_3, a first transfer chamber TFC1, and a second transfer chamber TFC2.

The first chamber 10_1 performs a lamination process, the second chamber 10_2 performs a transfer process, and the third chamber 10_3 performs a delamination process. The first, second and third chambers 10_1, 10_2, and 10_3 maintain a vacuum state when the lamination, transfer, and delamination processes are performed. The lamination, transfer, and delamination processes will be described in detail.

In embodiments, the first transfer chamber TFC1 is disposed between the first chamber 101 and the second chamber 10_2. The first transfer chamber TFC1 receives a substrate from the first chamber 10_1 and provides the substrate to the second chamber 10_2.

The first transfer chamber TFC1 includes a first transfer robot ROB1. The first transfer robot ROB1 receives the substrate from the first chamber 10_1 which is attached to the donor film, and transfers the substrate to the second chamber 10_2. The first transfer robot ROB1 includes a first robot arm R_A1. The substrate on which the lamination process is performed is loaded on the first robot arm R_A1.

The second transfer chamber TFC2 is disposed between the second chamber 10_2 and the third chamber 10_3. The second transfer chamber TFC2 receives the substrate from the second chamber 10_2 and provides the substrate to the third chamber 10_3.

The second transfer chamber TFC2 includes a second transfer robot ROB2. The second transfer robot ROB2 receives the substrate from the second chamber 10_2, on which the transfer process is performed, and transfers the substrate to the third chamber 10_3. The second transfer robot ROB2 includes a second robot arm R_A2. The substrate on which the transfer process is performed is loaded on the second robot arm R_A2.

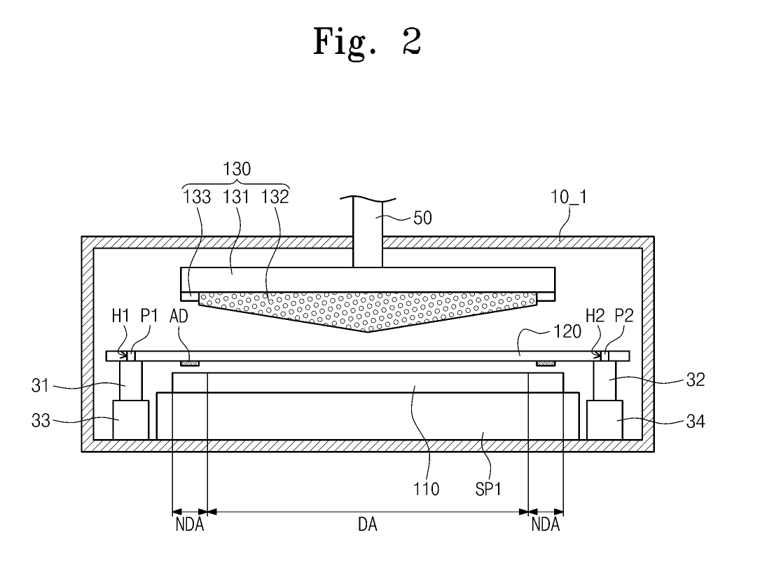

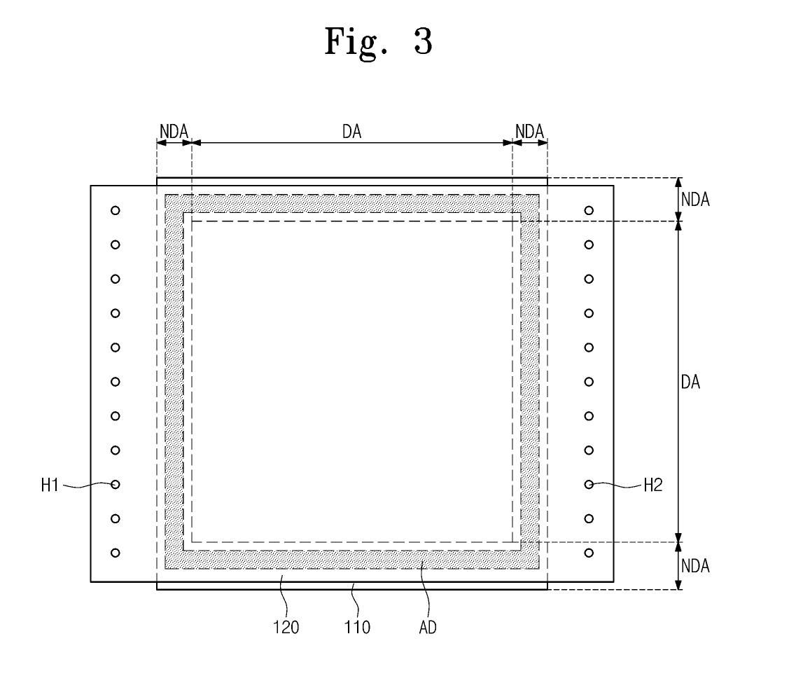

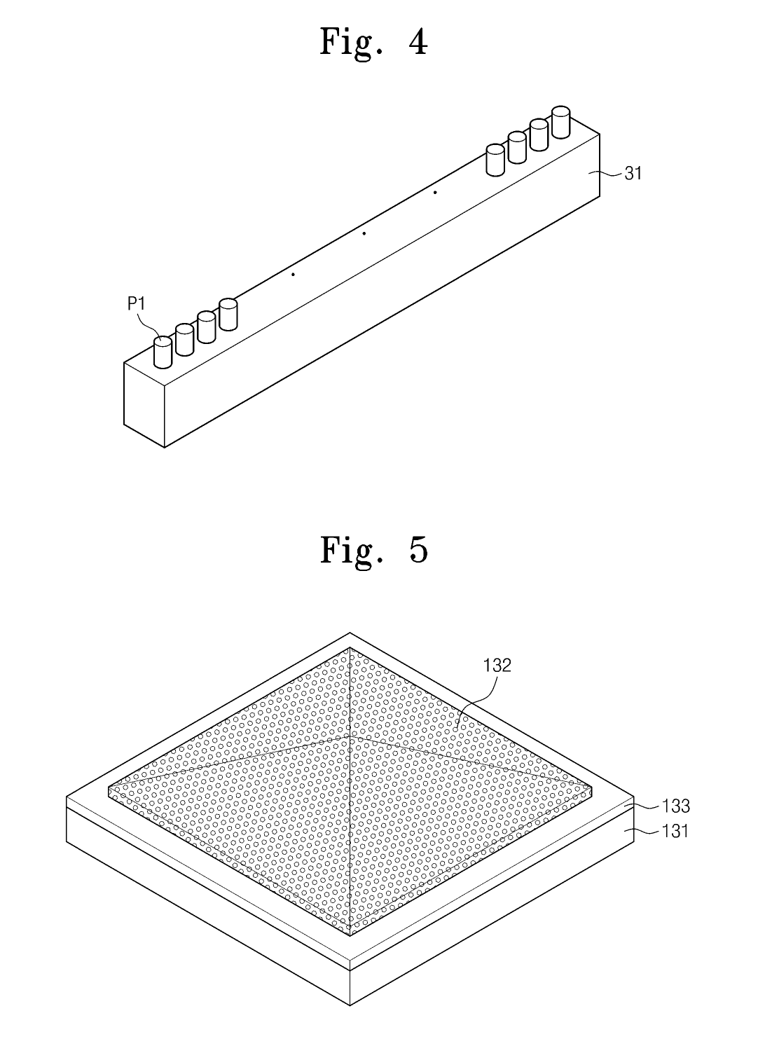

FIG. 2 is a view showing an inner configuration of the first chamber shown in FIG. 1, FIG. 3 is a plan view showing an arrangement of a donor film and the substrate shown in FIG. 1, FIG. 4 is a perspective view showing a first film supporter shown in FIG. 2, and FIG. 5 is a perspective view showing a press unit shown in FIG. 2.

Referring to FIGS. 2 to 5, the substrate 110, a first supporter SP1, a donor film 120, an adhesive member AD, first and second film supporters 31 and 32, first and second transfer units 33 and 34, a press unit 130, and a press unit transfer unit 50 are disposed in the first chamber 10_1 in which the lamination process is performed.

The first supporter SP1 is disposed at a lower portion in the first chamber 10_1. The substrate 110 is disposed on the first supporter SP1.

As shown in FIG. 3, the substrate 110 includes a deposition area DA and a non-deposition area NDA disposed to surround the deposition area DA when viewed in a plan view. The donor film includes a transfer layer 123 (refer to FIG. 7). The transfer layer 123 includes a deposition material, for example, an organic light emissive material. The deposition material is transferred to the deposition area DA and not transferred to the non-deposition area NDA.

The donor film 120 is disposed over the substrate 110 to face the substrate 110 and spaced apart from the substrate 110 at a predetermined distance. The adhesive member AD of an adhesive material is provided on a surface of the donor film 120 which faces the substrate 110. The adhesive member AD is disposed at a position corresponding to the non-deposition area NDA of the substrate 110 as shown in FIG. 3. In addition, the adhesive member AD is disposed to surround the deposition area DA when viewed in a plan view.

In FIG. 3, the adhesive member AD has a closed-loop shape, e.g., a rectangular shape, but it should not be limited to the rectangular shape. For instance, the closed-loop shape may be a circular shape, an oval shape, or a polygonal shape.

The first and second film supporters 31 and 32 are disposed at first and second side portions of the donor film 120 to support the donor film 120, respectively.

As shown in FIG. 3, the donor film 120 includes a plurality of first holes H1 formed at the first side portion of the donor film 120 and a plurality of second holes H2 formed at the second side portion of the donor film 120.

The first film supporter 31 includes a plurality of first protrusions P1 as shown in FIG. 4. Each of the first protrusions P1 is inserted into a corresponding first hole of the first holes H1.

For the convenience of explanation, only the first film supporter 31 has been shown in FIG. 4, but the first and second film supporters 31 and 32 have the same structure. That is, the second film supporter 32 includes a plurality of second protrusions P2 each of which is inserted into a corresponding second hole of the second holes H2.

The first protrusions P1 of the first film supporter 31 and the second protrusions P2 of the second film supporter 32 are inserted into the first holes H1 and the second holes H2 of the donor film 120, respectively, and thus the donor film 120 is flatly supported by the first and second film supporters 31 and 32. In embodiments, the donor film may be tensioned when the protrusions P1 and P2 engage with holes H1 and H2.

The first transfer unit 33 is disposed under the first film supporter 31 to upwardly and downwardly move the first film supporter 31. The second transfer unit 34 is disposed under the second film supporter 33 to upwardly and downwardly move the second film supporter 32.

The press unit 130 is disposed at an upper portion in the first chamber 10_1. The press unit 130 is disposed over the donor film 120 to be spaced apart from the donor film 120 at a predetermined distance. That is, the press unit 130 includes a pressing surface facing the substrate 110 while the donor film 120 is interposed between the substrate and the pressing surface.

The press unit 130 includes a press plate 131, a first elastic member 132, and a second elastic member 133 which are movable in a pressing direction toward the supporter. The first and second elastic members 132 and 133 are disposed under the press plate 131.

The second elastic member 133 is disposed to surround the first elastic member 132 when viewed in a pressing direction. The second elastic member 133 is disposed to overlap with the adhesive member AD when viewed in a pressing direction. Thus, the second elastic member 133 is disposed to correspond to the non-deposition area NDA of the substrate 110.

As an example, the second elastic member 133 has the same width as that of the adhesive member AD, but it should not be limited thereto or thereby. That is, the second elastic member 133 may have the width greater than that of the adhesive member AD.

Referring to FIG. 5, the first elastic member 132 has a thickness at a boundary thereof, which is thicker than a thickness of the second elastic member 133. For the convenience of explanation, FIG. 5 shows the perspective view of the press unit 130 upside down. The thickness of the first elastic member 132 becomes thick as it is closer to the center thereof. In the embodiments illustrated in FIG. 2, a pressing surface of the first elastic member is closer to the donor film 120 (or the substrate 110 or the supporter SP1) than a pressing surface of the second elastic material. Also, the first elastic material has the pressing surface closest to the donor film at its center, and the pressing surface farthest from the donor film at its boundary.

The second elastic member 133 has a stiffness or rigidity greater than that of the first elastic member 132. For instance, the second elastic member 133 may be formed of an elastic material, e.g., a rubber. In embodiments, the second elastic material may be made of a hard rubber. The first elastic member 132 may be formed of expanded polystyrene, e.g., Styrofoam, to have the stiffness or rigidity smaller than that of the rubber. Thus, the first elastic member is more easily deformed than the second elastic member.

The press unit transfer unit 50 is disposed on the press unit 130 and connected to the press unit 130. The press unit transfer unit 50 upwardly and downwardly moves the press unit 130. In detail, the press unit transfer unit 50 is connected to the press plate 131 of the press unit 130 to upwardly and downwardly move the press unit 130.

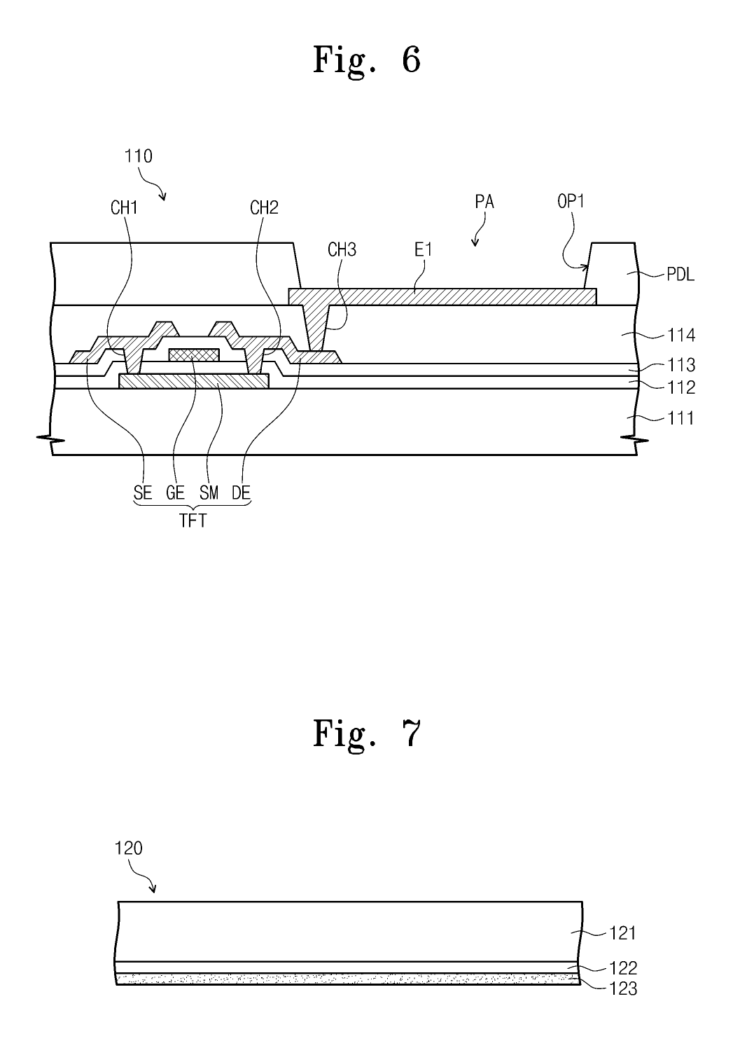

FIG. 6 is a cross-sectional view showing the substrate shown in FIG. 2, and the substrate shown in FIG. 6 may be used when an organic light emitting display device is manufactured.

Although not shown in figures, the substrate 110 includes a plurality of pixel areas. First electrodes are respectively arranged in the pixel areas and thin film transistors are respectively connected to pixel electrodes. For the convenience of explanation, FIG. 6 shows only one thin film transistor and only one pixel electrode connected to the thin film transistor.

Referring to FIG. 6, the substrate 110 includes a base substrate 111, a first insulating layer 112, a second insulating layer 113, a protective layer 114, a thin film transistor TFT, a first electrode E1, and a pixel defined layer PDL.

The base substrate 111 may be a transparent insulating substrate formed of glass, quartz, or ceramic or a transparent flexible substrate formed of plastic. The base substrate 111 may be a metal substrate formed of a stainless steel.

A semiconductor layer SM of the thin film transistor TFT is disposed over the base substrate 111. The semiconductor layer SM is formed of an inorganic semiconductor material, e.g., amorphous silicon or polysilicon, or an organic semiconductor material. In addition, the semiconductor layer SM may be formed oxide semiconductor. Although not shown in FIG. 6, the semiconductor layer SM includes a source area, a drain area, and a channel area disposed between the source area and the drain area.

The first insulating layer 112 is disposed over the base substrate 111 to cover the semiconductor layer SM. The first insulating layer 112 serves as a gate insulating layer.

A gate electrode GE of the thin film transistor TFT is disposed on the first insulating layer 112 to overlap with the semiconductor layer SM. In detail, the gate electrode GE is overlapped with the channel area of the semiconductor layer SM. The gate electrode GE is connected to a gate line (not shown) that applies on/off signals to the thin film transistor TFT.

The second insulating layer 113 is disposed on the first gate insulating layer 112 to cover the first gate insulating layer 112. The second insulating layer 113 serves as an inter-insulating layer

A source electrode SE and a drain electrode DE of the thin film transistor TFT are disposed on the second insulating layer 113 to be spaced apart from each other. The source electrode SE is connected to the semiconductor layer SM through a first contact hole CH1 formed through the first and second insulating layers 112 and 113. In detail, the source electrode SE is connected to the source area of the semiconductor layer SM.

The drain electrode DE is connected to the semiconductor layer SM through a second contact hole CH2 formed through the first and second insulating layers 112 and 113. In detail, the drain electrode DE is connected to the drain area of the semiconductor layer SM.

The protective layer 114 is disposed over the second insulating layer 113 to cover the source electrode SE and the drain electrode DE.

A first electrode E1 is disposed on the protective layer 114. The first electrode E1 is connected to the drain electrode DE of the thin film transistor TFT through a third contact hole CH3 formed through the protective layer 114.

The pixel defined layer PDL is disposed on the protective layer 114 to cover a boundary surface of the first electrode E1. The pixel defined layer PDL includes a first opening OP1 to expose a portion of the first electrode E1.

FIG. 7 is a cross-sectional view showing a structure of the donor film shown in FIG. 2.

Referring to FIG. 7, the donor film 120 includes a base film 121, a light-heat conversion layer 122 disposed under the base film 121, and a transfer layer 123 disposed under the light-heat conversion layer 122.

The base film 121 is formed of a transparent polymer organic material, such as polyethyleneterephthalate (PET), polyethylenenaphthalate (PEN), polyethylene (PE), polycarbonate (PC), etc.

The light-heat conversion layer 122 converts light incident thereto to heat. The light-heat conversion layer 122 includes a light absorbing material, e.g., aluminum oxide, aluminum sulfide, carbon black, graphite, or infrared ray dye.

When the substrate 110 is a substrate for the organic light emitting display device, the transfer layer 123 may be an organic transfer layer. The organic transfer layer includes a hole injection layer, a hole transporting layer, a light emission layer, an electron transporting layer, and an electron injection layer. The transfer layer 123 is disposed to face the substrate 110.

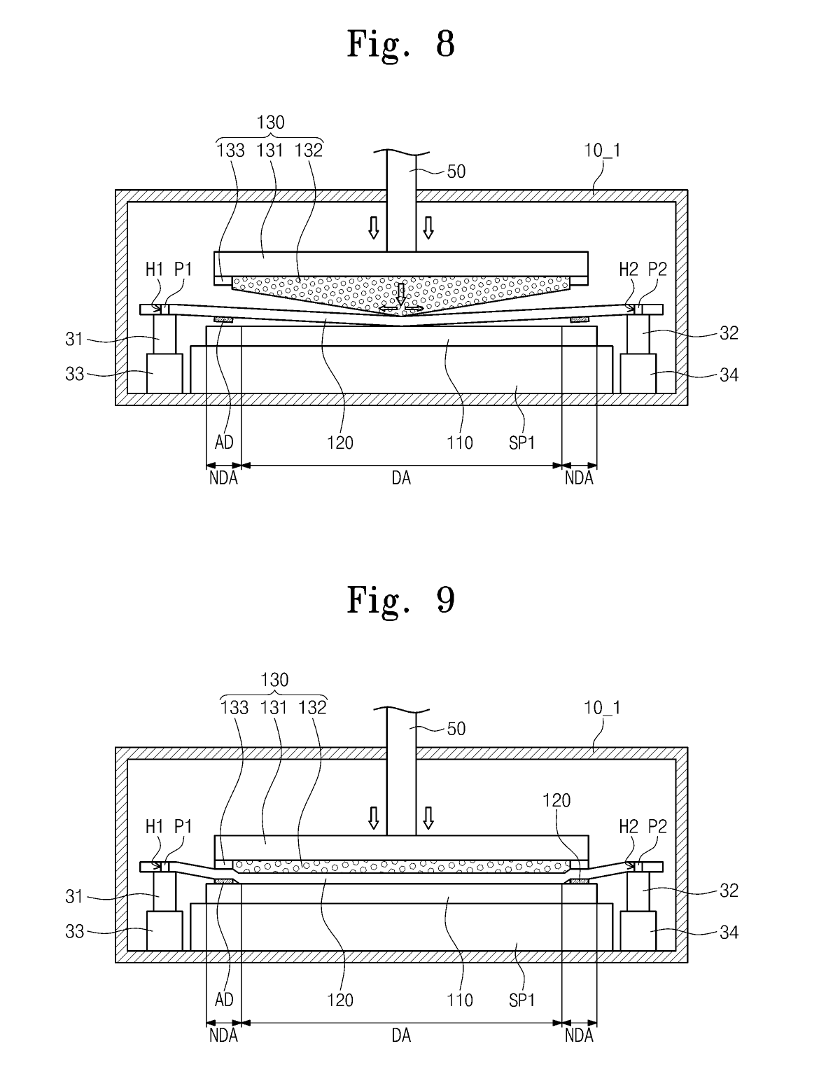

FIGS. 8 to 10 are views showing a lamination process performed in the first chamber shown in FIG. 1.

Referring to FIG. 8, the press unit transfer unit 50 downwardly moves the press unit 130. The press unit 130 presses the donor film 120 to the substrate 110 to laminate the donor film 120 over the substrate 110.

In detail, the first elastic member 132 has the thickness thicker than that of the second elastic member 133 and the thickness of the first elastic member 132 is greatest at the center of the first elastic member 132. Accordingly, the center of the first elastic member 132 of the press unit 130 first makes contact with a center of the donor film 120, and thus the donor film 120 is pressed toward the substrate 110. As a result, the center of the donor film 120 first makes contact with the substrate 110 and is pressed toward the substrate 110.

As the press unit 130 downwardly moves, a periphery of the first elastic member 132 subsequently makes contact with the donor film 120. That is, the contact area between the first elastic member 132 and the donor film 120 increases from the center to the periphery. Therefore, the donor film 120 is pressed toward the substrate 110 by making contact the first elastic member 132 with the donor film 120. As a result, the center and the periphery of the donor film 120 sequentially make contact with the substrate 110 to be pressed to the substrate 110. That is, the contact area between the donor film 120 and the substrate 110 is increased as the press unit 130 moves down.

As the contact area between the first elastic member 132 and the donor film 120 increases, the first elastic member 132 is deformed and contracted.

Referring to FIG. 9, as the press unit 130 downwardly moves, the contact area between the first elastic member 132 and the donor film 120 becomes wider from the center to the periphery. In addition, the contact area between the donor film 120 and the substrate 110 becomes wider from the center to the periphery. Thus, the donor film 120 may be pressed to the substrate 110 throughout the deposition area DA.

In a case that the entire portion of the donor film 120 is pressed to the substrate 110 at the same time, the donor film 120 having flexibility may not be pressed to the substrate 110 at the same time. In this case, a delamination phenomenon, in which a predetermined space is formed between the donor film 120 and the substrate 110, occurs. That is, the donor film 120 is not uniformly pressed to the substrate 110, so that a transfer defect occurs.

However, the center of the donor film 120 is first pressed to the substrate 110 due to the compression of the first elastic member 132 having the thickness greatest at the center thereof. Then, the contact area between the first elastic member 132 and the donor film 120 becomes wider from the center to the periphery and the contact area between the donor film 120 and the substrate 110 becomes wider from the center to the periphery. That is, the center and the periphery of the donor film 120 are sequentially pressed to the substrate. Therefore, the donor film 120 may be uniformly pressed to the substrate 110. As a result, the delamination phenomenon may be prevented.

The donor film 120 is pressed to the deposition area DA of the substrate 110 and the second elastic member 133 makes contact with the donor film 120 in the non-deposition area NDA. The second elastic member 133 presses the donor film 120 to the substrate 110 in the non-deposition area NDA.

The second elastic member 133 is disposed to overlap with the adhesive member AD. Accordingly, when the press unit 130 downwardly moves even after all the press surface of the first elastic member contacts the donor film, a force generated by the second elastic member 133 is applied to the adhesive member AD disposed under the donor film 120. Thus, the adhesive member AD is pressed to the substrate 110 in the non-deposition area NDA and attached to the substrate 110. As a result, the donor film 120 and the substrate 110 are attached to each other and fixed to each other in the non-deposition area NDA by the adhesive member AD.

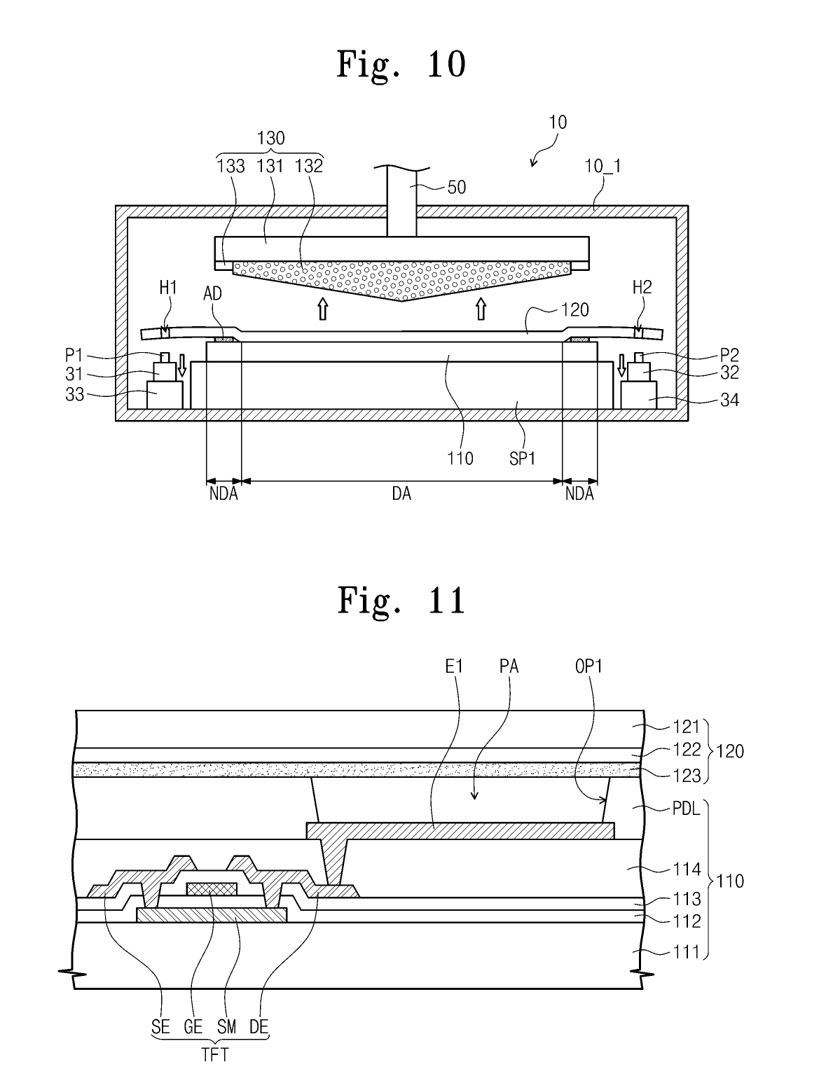

Referring to FIG. 10, when the donor film 120 is pressed to and fixed to the substrate 110, the press unit 130 upwardly moves by the press unit transfer unit 50. The first transfer unit 33 downwardly moves the first film supporter 31 and the second transfer unit 34 downwardly moves the second film supporter 32.

Consequently, the donor film 120 may be fixed to the substrate 110 according to the laser induced thermal imaging apparatus 100 and the laser induced thermal imaging method using the apparatus 100.

Although not shown in figures, the first supporter SP1 shown in FIG. 2 may include recesses formed on an upper portion thereof and extended in a predetermined direction. The first robot arm R_A1 of the first transfer robot ROB1 moves to the first chamber 10_1 and is inserted into the recesses of the first supporter SP1. The first robot arm R_A1 inserted into the recesses of the first supporter SP1 upwardly moves to load the substrate 110 thereon. The first transfer robot ROB1 transfers the substrate 110 to the second chamber 10_2 via the first transfer chamber TFC1.

FIG. 11 is a cross-sectional view showing the donor film compressed onto the substrate.

Referring to FIG. 11, the transfer layer 123 of the donor film 120 is disposed to face the substrate 110. Thus, the transfer layer 123 of the donor film 120 is disposed over the pixel defined layer PDL of the substrate 110 to make contact with the pixel defined layer PDL of the substrate 110. The transfer layer 123 of the donor film 120 is disposed to be spaced apart from the first electrode E1 at a predetermined distance in an area corresponding to the first opening OP1 of the pixel defined layer PDL.

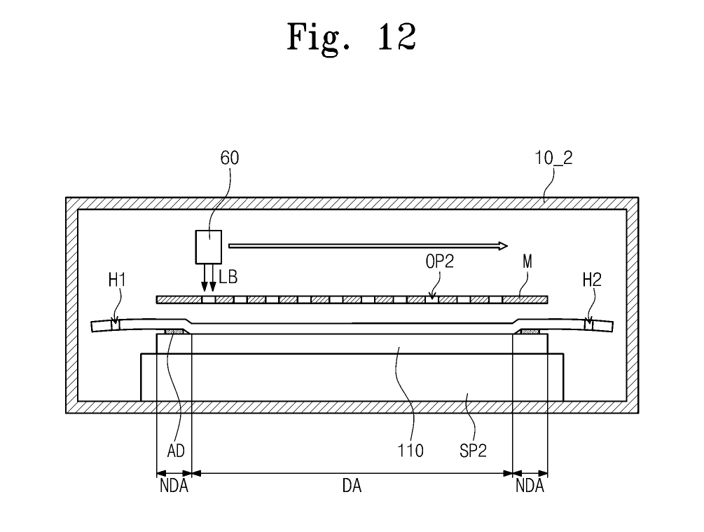

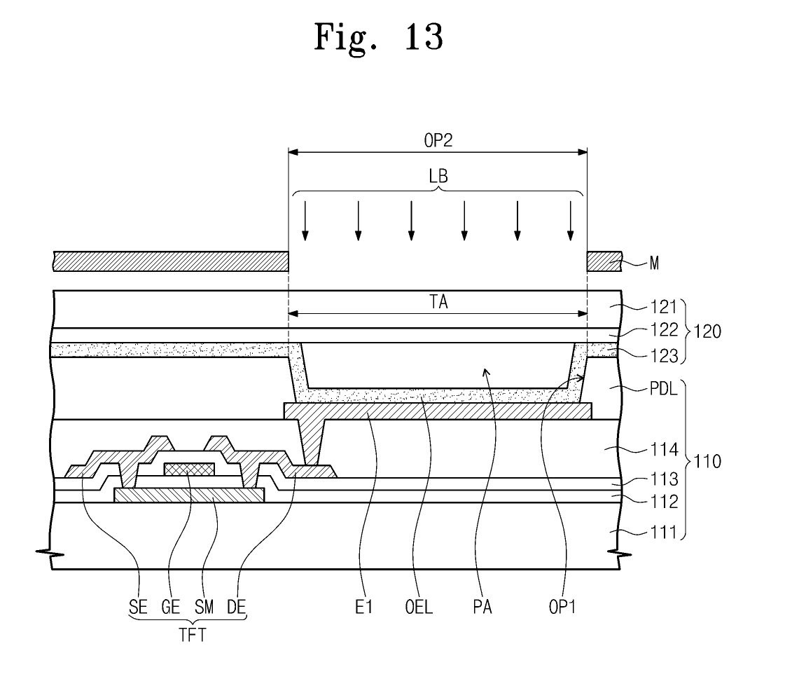

FIG. 12 is a view showing an inner configuration of the second chamber shown in FIG. 1 and FIG. 13 is a view showing a transfer process performed in the second chamber shown in FIG. 12.

Referring to FIGS. 12 and 13, the substrate 110 is disposed on a second supporter SP2 disposed at a lower portion of the second chamber 10_2. The substrate 110 is loaded into the second chamber 10_2 after the lamination process is performed on the substrate 110 in the first chamber 10_1. A laser beam irradiation unit 60 is disposed at an upper portion of the second chamber 10_2 to generate a laser beam LB.

The transfer process is performed in the second chamber 10_2. In detail, a mask M is disposed over the donor film 120 to be spaced apart from the donor film 120 at a predetermined distance. The mask M includes a plurality of second openings OP2.

The pixel areas PA of the substrate 110 are disposed in the deposition area DA. For the convenience of explanation, FIG. 13 shows only one pixel area PA. The second openings OP2 of the mask M are disposed to correspond to the deposition area DA of the substrate 110. In addition, the second openings OP2 of the mask M correspond to the pixel areas PA of the substrate 110 and are disposed to overlap with the pixel areas PA.

The laser beam irradiation unit 60 is disposed over the mask M and irradiates the laser beam LB to the donor film 120. The laser beam LB is provided to transfer areas TA of the donor film 120 corresponding to the second openings OP2 after passing through the second openings OP2.

The transfer areas TA of the donor film 120 are areas to which the transfer layer 123 is transferred. For the convenience of explanation, FIG. 13 shows only one transfer area TA, but the transfer areas TA corresponding to the second openings OP2 may be defined in the donor film 120.

When the laser beam LB is irradiated, the light-heat conversion layer 122 is expanded to the substrate 110, and thus the transfer layer 123 is expanded. Accordingly, the transfer layer 123 corresponding to the transfer areas TA, onto which the laser beam LB is irradiated, is separated from the donor film 120 and transferred to the substrate 110.

Although not shown in figures, the second supporter SP2 shown in FIG. 13 may include recesses formed on an upper portion thereof and extended in a predetermined direction. The second robot arm R_A2 of the second transfer robot ROB2 moves to the second chamber 10_2 and is inserted into the recesses of the second supporter SP2. The second robot arm R_A2 inserted into the recesses of the second supporter SP2 upwardly moves to load the substrate 110 thereon. The second transfer robot ROB2 transfers the substrate 110 to the third chamber 10_3 via the second transfer chamber TFC2.

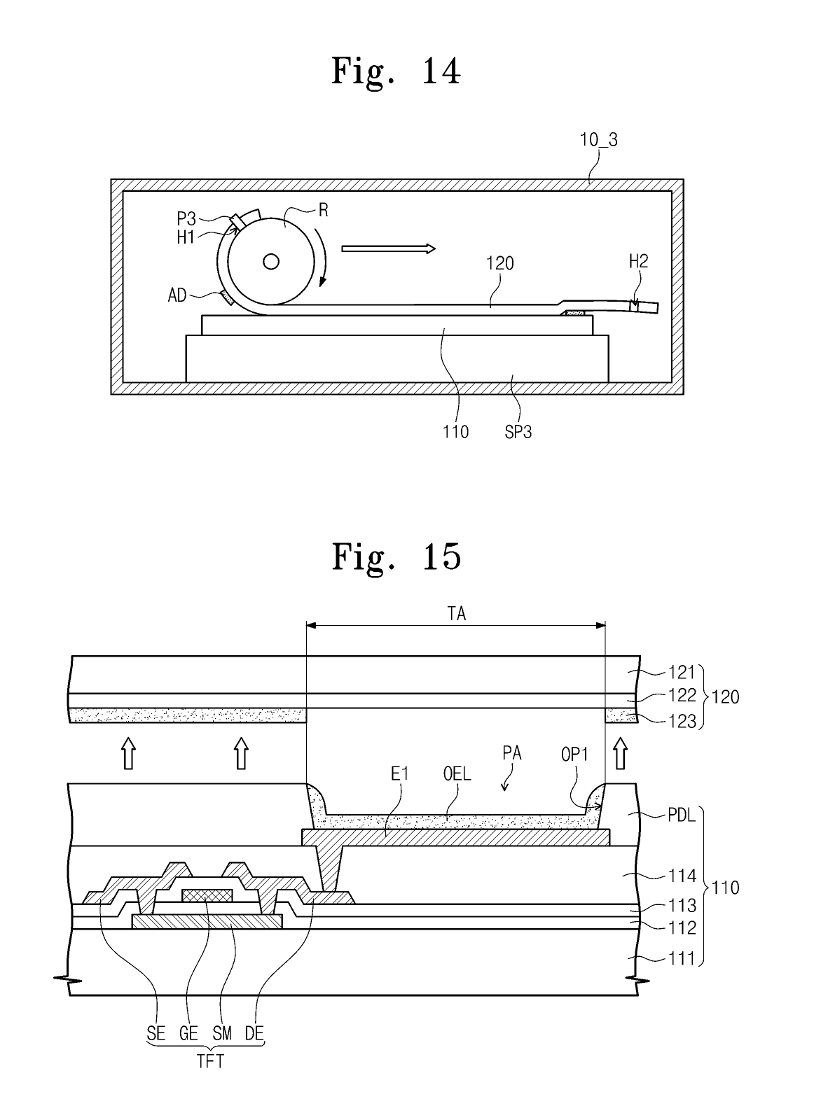

FIG. 14 is a view showing an inner configuration of the third chamber shown in FIG. 1 and FIG. 15 is a view showing the delamination process performed in the third chamber shown in FIG. 14.

Referring to FIGS. 14 and 15, the substrate 110 is disposed on a third supporter SP3 disposed at a lower portion of the third chamber 10_3 after the transfer process is performed on the substrate 110.

A delamination roller R is disposed on the transfer film 120. The delamination roller R includes third protrusions P corresponding to the first holes H1. The delamination roller R is disposed at a side portion of the donor film 120 and the third protrusions P of the delamination roller R are inserted into the first holes H1 of the third protrusions P.

The delamination roller R rotates in a clockwise direction to delaminate the donor film 120 from the substrate 110. The transfer layer 123 in the transfer areas TA to which the laser beam LB is irradiated is transferred to the first openings OP1 of the substrate 100. Accordingly, the transfer layer 123 remaining in areas of the donor film 120 except for the transfer areas TA is delaminated from the substrate 110.

Although not shown in figures, the third protrusions P of the delamination roller R may be inserted into the second holes H2 formed through the other end portion of the donor film 120 instead of being inserted into the first holes H1. In this case, the delamination roller R rotates in a counter-clockwise direction to delaminate the donor film 120 from the substrate 110.

The transfer layer 123 transferred to the first openings OP1 of the substrate 110 may be an organic light emitting layer OEL.

The laser induced thermal imaging apparatus 100 may sequentially press the donor film 120 to the substrate 110 using the first and second elastic members 132 and 133 during the lamination process. In addition, the laser induced thermal imaging apparatus 100 may fix the donor film 120 and the substrate 110 to each other using the adhesive member AD during the lamination process.

Consequently, the donor film 120 may be sequentially compressed to and fixed to the substrate 110 according to the laser induced thermal imaging apparatus 100 and the laser induced thermal imaging method using the apparatus 100.

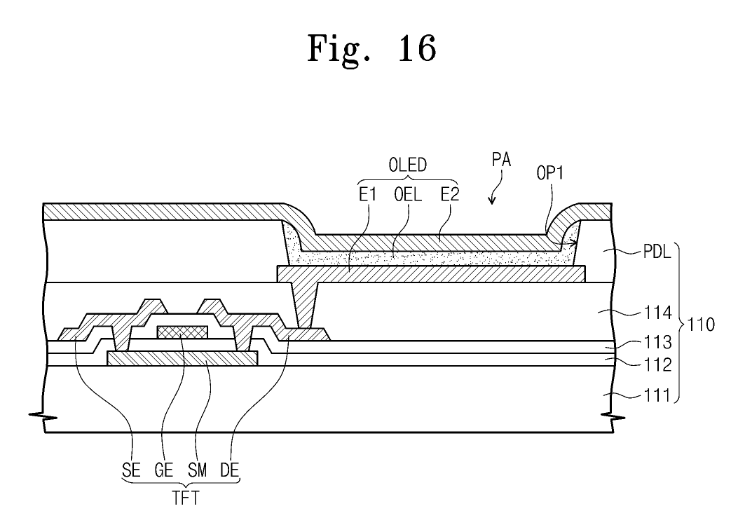

FIG. 16 is a cross-sectional view showing an organic light emitting device manufactured after the laser induced thermal imaging process is performed.

Referring to FIG. 16, a second electrode E2 is disposed on the pixel defined layer PDL and the organic light emitting layer OEL. The second electrode E2 may be a common electrode or a cathode electrode.

The first electrode E1 may serve as a pixel electrode or an anode electrode. The first electrode E1 may be a transmission type electrode or a reflection type electrode. When the first electrode E1 is the transmission type electrode, the first electrode E1 may include indium tin oxide (ITO), indium zinc oxide (IZO), or zinc oxide (ZnO). When the first electrode E1 is the reflection type electrode, the first electrode E1 may include a reflection layer formed of Ag, Mg, Al, Pt, Pd, Au, Ni, Nd, Ir, Cr, or a compound thereof and a transparent conductive layer formed of ITO, IZO, or ZnO.

The organic light emitting layer OEL includes an organic material that generates a light with a red color, a green color, or a blue color. Accordingly, the organic light emitting layer OEL generates a red light, a green light, or a blue light, but it should not be limited thereto or thereby. That is, the organic light emitting layer OEL may generate a white light obtained by combining organic materials generating the red, green, and blue lights.

The organic light emitting layer OEL may be formed of a low molecular organic material or a high molecular organic material. Although not shown in figures, the organic light emitting layer OEL has a multi-layer structure of a hole injection layer, a hole transporting layer, an emission layer, an electron transporting layer, and an electron injection layer. As an example, the hole injection layer is disposed on the first electrode E1, and the hole transporting layer, the emission layer, the electron transporting layer, and the electron injection layer are sequentially stacked over the hole injection layer.

The second electrode E2 may be a transmission type electrode or a reflection type electrode. When the second electrode E2 is the transmission type electrode, the second electrode E2 includes a layer formed by depositing Li, Ca, LiF/Ca, LiF/Al, Al, Mg, or a compound thereof and an auxiliary electrode formed on the layer using a transparent conductive material, e.g., ITO, IZO, or ZnO. When the second electrode E2 is the reflection type electrode, the second electrode E2 is formed of Ag, Mg, Al, Pt, Pd, Au, Ni, Nd, Ir, Cr, Li, Ca, LiF/Ca, LiF/Al, or a compound thereof.

When an organic light emitting display device is a front surface light emitting type, the reflection type electrode is used as the first electrode E1 and the transmission type electrode is used as the second electrode E2. When the organic light emitting display device is a rear surface light emitting type, the first electrode E1 is the transmission type electrode and the second electrode E2 is the reflection type electrode.

The organic light emitting device OLED is formed by the first electrode E1, the organic light emitting layer OEL, and the second electrode E2 in the pixel area PA. That is, the organic light emitting device OLED is formed in the pixel area PA and includes the first electrode E1, the organic light emitting layer OEL, and the second electrode E2 in the pixel area PA.

The first electrode E1 may be a hole injection electrode, i.e., a positive electrode, and the second electrode E2 may be an electron injection electrode, i.e., a negative electrode, but they should not be limited thereto or thereby. That is, the first electrode E1 may be the negative electrode and the second electrode E2 may be the positive electrode according to the driving method of the organic light emitting diode display.

A driving voltage is applied to the first electrode E1 and a voltage having an opposite polarity to that of the driving voltage is applied to the second electrode E2 by the thin film transistors TFT, and thus the organic light emitting layer OEL emits the light. In this case, holes and electrons injected into the organic light emitting layer are recombined in the organic light emitting layer to generate excitons, and the organic light emitting device OLED emits the light by the excitons that return to a ground state from an excited state. Accordingly, the organic light emitting device OLED emits the red light, the green light, and the blue light according to a current flow, thereby displaying predetermined image information.

Although the exemplary embodiments of the present invention have been described, it is understood that the present invention should not be limited to these exemplary embodiments but various changes and modifications can be made by one ordinary skilled in the art within the spirit and scope of the present invention as hereinafter claimed.

What is claimed is:

1. A laser induced thermal imaging apparatus comprising:
a substrate support configured to support a substrate;
a donor film holder configured to hold a donor film at a position over the substrate support; and
a press unit comprising a first elastic member and a second elastic member disposed over the substrate support, and configured to move the first and second elastic members in a pressing direction toward the substrate support for pressing the donor film to the substrate to laminate the donor film onto the substrate,
wherein the second elastic member surrounds the first elastic member when viewed in the pressing direction and is more rigid than the first elastic member.

2. The apparatus of claim 1, wherein the first elastic member has a thickness at a boundary thereof, which is greater than a thickness of the second elastic member, wherein the first elastic member has a first thickness at a first position and a second thickness at a second position which is closer to the boundary than the first position when viewed in the pressing direction, wherein the first thickness is greater than the second thickness.

3. The apparatus of claim 2, wherein the press unit further comprises a press plate comprising a surface facing the substrate support, and the first and second elastic members are disposed over the surface of the press plate to face the substrate support.

4. The apparatus of claim 1, wherein the first and second elastic members are configured to move in the pressing direction to press the donor film to the substrate, and the donor film and the substrate are attached to each other in a non-deposition area of the substrate by an adhesive material.

5. The apparatus of claim 1, wherein the donor film holder comprise first and second film supporters placed at both side portions of the donor film to support the donor film.

6. The apparatus of claim 5, wherein the donor film comprises:
a transfer layer that comprises the deposition material comprising an organic light emissive material for forming an organic light emitting layer over the substrate;
a plurality of first holes formed through a first side portion of the donor film; and
a plurality of second holes formed through a second side portion of the donor film.

7. The apparatus of claim 6, wherein the first film supporter comprises a plurality of first protrusions configured to engage with the first holes, and the second film supporter comprises a plurality of second protrusions configured to engage with the second holes to support the donor film at the first and second side portions.

8. The apparatus of claim 7, further comprising:
a first chamber that accommodates the substrate support, the donor film holder and the press unit so as to laminate the donor film over the substrate therein; and
a second chamber configured to receive the substrate, on which the donor film is laminated, from the first chamber;
a mask disposed in the second chamber and comprising a plurality of openings; and
a laser beam irradiation unit disposed over the mask in the second chamber, and configured to irradiate a laser beam onto the donor film received in the second chamber through the openings such that the deposition material is transferred onto the substrate.

9. The apparatus of claim 8, further comprising:
a third chamber configured to receive the substrate on which the deposition material is transferred; and
a delamination roller disposed in the third chamber, comprising a plurality of third protrusions configured to engage with the first holes, and configured to roll to delaminate the donor film from the substrate.

10. A method of making a light emitting device comprising an organic emissive layer, the method comprising:
providing a substrate comprising a deposition surface that includes a deposition area and a non-deposition area surrounding the deposition area;
providing a donor film comprising an adhesive material and a deposition material on a transfer surface thereof such that the transfer surface faces the substrate;
providing a press unit movable along a pressing direction and comprising a first elastic member and a second elastic member surrounding the first elastic member when viewed in the pressing direction, wherein the second elastic member is more rigid than the first elastic member;
arranging the press unit, the donor film and the substrate such that the donor film is located between the press unit and the substrate; and
moving the first and second elastic members of the press unit toward the donor film to press the donor film onto the substrate, thereby laminating the donor film on the substrate, wherein the second elastic member presses the donor film such that the adhesive material is attached to the non-deposition area.

11. The method of claim 10, wherein the first elastic member has a thickness at a boundary thereof, which is greater than a thickness of the second elastic member, and wherein the first elastic member has a first thickness at a first position and a second thickness at a second position which is closer to the boundary than the first position when viewed in the first direction, and the first thickness is greater than the second thickness.

12. The method of claim 11, wherein the pressing of the donor film onto the substrate comprises:
making a center portion of the first elastic member in contact with the donor film, thereby pressing a center portion of the donor film onto the substrate;
subsequently, making a periphery portion of the first elastic member in contact with the donor film, thereby pressing a periphery portion of the donor film onto the substrate; and
subsequently, making the second elastic member in contact with the donor film to press the donor film onto the substrate, thereby attaching the substrate to the donor film using the adhesive material in the non-deposition area.

13. The method of claim 12, wherein the press unit further comprises a press plate comprising a surface facing the donor film, and the first and second elastic members are disposed over the surface of the press plate.

14. The method of claim 10, further comprising first and second film supporters placed at both side portions of the donor film to hold the donor film.

15. The method of claim 14, wherein the donor film comprises:
a transfer layer that faces the substrate and comprises the deposition material comprising an organic light emissive material for forming an organic light emitting layer over the substrate;
a plurality of first holes formed through a first side portion of the donor film; and
a plurality of second holes formed through a second side portion of the donor film.

16. The method of claim 15, wherein the first film supporter comprises a plurality of first protrusions configured to engage with the first holes, and the second film supporter comprises a plurality of second protrusions configured to engage with the second holes to support the donor film at the first and second side portions.

17. The method of claim 10, further comprising:
disposing a mask over the donor film laminated to the substrate, the mask being provided with a plurality of openings;
irradiating a laser beam onto the donor film through the openings; and
transferring the deposition material disposed on the donor film to the substrate.

18. The method of claim 17, further comprising:
disposing a delamination roller at the first side portion of the donor film, the delamination roller comprising a plurality of third protrusions;
inserting the third protrusions into the first holes; and
rotating the delamination roller to delaminate the donor film from the substrate.

19. A method of making a light emitting device comprising an organic light emissive layer, the method comprising:
providing a substrate support and a press unit configured to move along a pressing direction toward the substrate support, the press unit comprising:
a first press member comprising a first press surface, and
a second press member comprising a second press surface and surrounding the first press member when viewed in the pressing direction,
wherein the first press surface is closer to the support than the second press surface;
providing a substrate comprising a plurality of layers and a deposition surface;
providing a donor film comprising a transfer surface and an organic light emissive material and an adhesive material which are provided on the transfer surface such that the adhesive material surrounds the adhesive material when viewed in the pressing direction;
arranging the substrate and the donor film between the substrate support and the press unit such that the donor film is located between the substrate and the press unit and further such that the second press member overlaps the adhesive material when viewed in the pressing direction;
moving the first and second press members along the pressing direction toward the stage to press the donor film to the substrate, thereby attaching the donor film to the substrate using the adhesive material, wherein, while pressing, the organic light emissive material first contacts the substrate, and subsequently the adhesive material contacts and is attached to the substrate.

20. The method of claim 19, wherein, when pressing, the first and second press members moves together, wherein the first press member is more deformable than the second press member.
